(19) United States
(12) Patent Application Publication
(10) Pub. No.: US 2024/0215190 A1
(43) Pub. Date: Jun. 27, 2024

(54) Display Apparatus

(71) Applicant: LG Display Co., Ltd., Seoul (KR)

(72) Inventors: Hyeonyeong Lee, Sejong-si (KR); Kwangmin Hyun, Daegu (KR)

(21) Appl. No.: 18/542,571

(22) Filed: Dec. 15, 2023

(30) Foreign Application Priority Data
Dec. 27, 2022 (KR) 10-2022-0185216

(51) Int. Cl. H05K 5/03

(52) U.S. Cl. CPC H05K 5/03

(57) ABSTRACT

There is disclosed a display apparatus including a display panel comprising a display area having a plurality of sub-pixels and a non-display area surrounding the display area and having a bending area; a first back plate and a second back plate disposed under the display panel and spaced apart from each other; and an adhesion assembly attaching the first back plate and the second back plate to a lower surface of the display panel. The adhesion assembly may have a multilayer structure in which a plurality of adhesive layers with different storage moduli are disposed.

### CROSS-REFERENCE TO RELATED APPLICATION

This application claims priority to and benefit of Korean Patent Application No. 10-2022-0185216 filed on Dec. 27, 2022, which is hereby incorporated by reference as if fully set forth herein.

### BACKGROUND

### Technical Field

The present disclosure relates to a display apparatus, more particularly, a display apparatus that may simplify a manufacturing process while reducing a bezel side.

### Background of the Disclosure

Specific examples of a flat panel display device includes a liquid crystal display apparatus, an organic light emitting display apparatus, an inorganic light emitting display apparatus, and a quantum dot display apparatus, etc.

Efforts are being made to minimize the size of a non-display area (or bezel area) of a display apparatus that is visible to users in order to provide a sense of immersion and aesthetics.

Recently, a flexible display apparatus including a display panel using a flexible substrate has been developed and the flexible display apparatus has an advantage of being designed in various shapes.

In case of such a flexible display apparatus, the size of a non-display area (or bezel area) may be reduced by folding or bending a portion of the non-display area of the display panel and placing it under a display area (or active area).

### SUMMARY

To support a display panel using a flexible substrate, a back plate may be attached to a lower surface of the display panel, that is, a lower surface of the flexible substrate by an optically clear adhesive. In order to make the display panel easy to bend and implement a narrower bezel area, the back plate is not attached to a bending area of the display panel. In other words, a first back plate with a relatively large area and a second back plate with a relatively small area may be attached to the lower surface of the display panel, spaced apart from each other by a dimension of the bending area.

In case of a foldable display apparatus that is one of flexible display apparatuses, internal components are attached inside the display apparatus by an optically clear adhesive layer having a low storage modulus of several tens of kPa to alleviate stress in a folding area of the display apparatus.

Typically, a plurality of unit cells (one unit cell is corresponding to one display panel) are formed on a mother substrate and then cut to be separated into individual display panels. Before being separated into individual display panels, the back plate is attached to the lower surface of the mother substrate.

The optically clear adhesive layer having a low storage modulus of several tens of kPa may have a high adhesive force so that it is difficult to remove it after the attaching. Accordingly, a back plate for unit cell including a first back plate and a second back plate spaced apart from each other by a distance corresponding to a bending area may be fabricated in advance to be used.

The back plate for the unit cell includes the first back plate and the second back plate disposed on a protection film, spaced apart from each other, an optically clear adhesive disposed on the first back plate and the second back plate, respectively, and the optically clear adhesives covered with a release film.

To attach one back plate for unit cell to the unit cell (i.e., unit display panel) formed on the mother substrate, the release film may be removed first, the first and second back plates may be attached, and the protection film may be removed finally.

Since the back plate for unit cell has to be attached to every unit cell formed on the mother substrate, the manufacturing cost and time of the display apparatus increases due to the process of attaching the back plate. As the number of cells increases, the manufacturing cost and time of the display apparatus further increases due to the process of attaching the back plate.

Accordingly, there is a need for a method that may simplify the process of attaching the back plate and reduce the manufacturing cost.

Inventors of the present disclosure invented a display apparatus that may simplify the process of attaching the back plate and reduce the manufacturing cost.

One objective of the present disclosure is to provide a display apparatus that may simplify the process of attaching the back plate and reduce the manufacturing cost, while reducing the size of a bezel area.

Aspects and objects according to the present disclosure are not limited to the above ones, and other aspects and advantages that are not mentioned above can be clearly understood from the following description and can be more clearly understood from the embodiments set forth herein by people skilled in the art.

A display apparatus according to an embodiment of the present disclosure may include a display panel comprising a display area having a plurality of sub-pixels and a non-display area surrounding the display area and having a bending area; a first back plate and a second back plate disposed under the display panel and spaced apart from each other; and an adhesion assembly attaching the first back plate and the second back plate to a lower surface of the display panel. The adhesion assembly may have a multilayer structure in which a plurality of adhesive layers with different storage moduli are disposed.

The display apparatus according to the embodiments of the present disclosure may include a flexible display panel; a back plate disposed under the flexible display panel; and an adhesion assembly attaching the back plate to a lower surface of the flexible display panel. The adhesion assembly may include a first adhesive layer contacting the back plate; and a second adhesive layer contacting the flexible display panel, and the second adhesive layer may have a larger storage modulus than the first adhesive layer.

Detailed descriptions of other embodiments are included in the following description and the accompanying drawings.

The display apparatus according to the embodiments of the present disclosure may use the adhesion assembly in which the adhesive layers with different storage moduli are multilayered and the upper adhesive layer attached to the display panel is a variable adhesive layer, for example. Accordingly, after the mother back plate is attached to the mother substrate, some area of the mother back plate disposed in the bending areas of the plurality of display panels aligned in the same column may be removed at once, thereby simplifying the process of attaching the back plate and reducing the manufacturing time and cost.

According to the embodiments of the present disclosure, the adhesive layer attached to the lower surface of the display panel may have the black or gray color. Accordingly, the external incident light having passed through the display panel may be absorbed by the adhesive layer, thereby improving the visibility of the display panel.

In addition to the above-described effects, specific effects of the present invention will be described together with the following detailed description for implementing the present invention.

### BRIEF DESCRIPTION OF DRAWINGS

FIG. 1 is a plan view showing a state where a display apparatus according to an embodiment of the present disclosure is not bent;

FIG. 2 is a rear view showing a state where a display apparatus according to an embodiment of the present disclosure is not bent;

FIG. 3 is a sectional view cut away along 3-3 of FIG. 1;

FIG. 4 is a sectional view showing that a display apparatus of FIG. 3 is bent;

FIGS. 5 and 6 are views showing a process of attaching a back plate according to an embodiment of the present disclosure to a display panel.

### DETAILED DESCRIPTIONS

The above objects, features, advantages and methods to achieve them will be described later in detail with reference to the accompanying drawings, and accordingly, those skilled in the art to which the present invention belongs will be able to easily implement the technical idea of the present invention. In describing the present invention, if it is determined that the detailed description of the known technology related to the present invention may unnecessarily obscure the subject matter of the present invention, the detailed description will be omitted.

Hereinafter, preferred embodiments according to the present invention will be described in detail with reference to the accompanying drawings. In the drawings, the same reference numerals are used to indicate the same or similar components, the present disclosure should be construed to extend to any alterations, equivalents and substitutes in addition to those which are particularly set out in the accompanying drawings. Terms of respective elements used in the following description are terms defined taking into consideration of the functions obtained in the present invention. Therefore, these terms do not limit technical elements in the present invention. Further, the defined terms of the respective elements will be called other terms in the art. Terminology that is used in the present disclosure is limited to only for embodiments herewith but made only to make it easy to understand the present disclosure. A singular representation may include a plural representation unless it represents a definitely different meaning from the context. Terms such as “include” or “has” are used herein and should be understood that they are intended to indicate an existence of several components, functions or steps, disclosed in the specification, and it is also understood that greater or fewer components, functions, or steps may likewise be utilized.

In understanding the components, it should be understood as including the error range even if there is no separate explicit description.

It will be understood that when an element is referred to as being “connected with” another element, the element can be directly connected with the other element or intervening elements may also be present. In contrast, when an element is referred to as being “directly connected with” another element, there are no intervening elements present.

When describing time relationship, for example, ‘after’, ‘as soon as’, ‘right after or next’, ‘before’, etc. or, unless ‘immediately’ or ‘directly’ is used, non-continuous cases may be included.

It will be understood that although the terms first, second, etc. may be used herein to describe various elements, these elements should not be limited by these terms. These terms are generally only used to distinguish one element from another.

Features of various embodiments may be partially or entirely combined with each other, and various connections and driving are possible. Also, embodiments may be implemented independently or implemented in a related relationship.

Hereinafter, a display apparatus according to embodiments of the present disclosure will be described referring to the accompanying drawings.

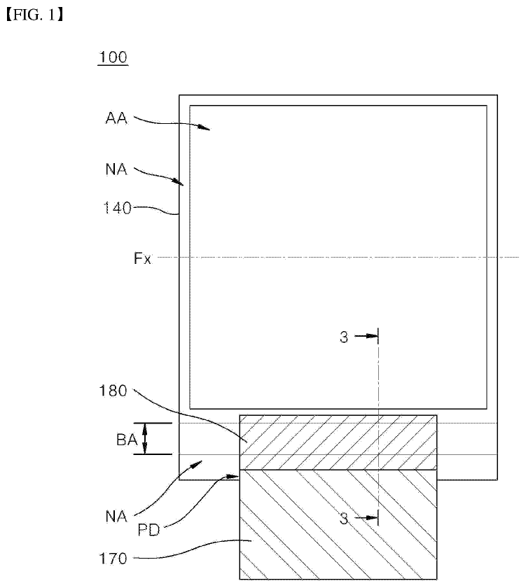

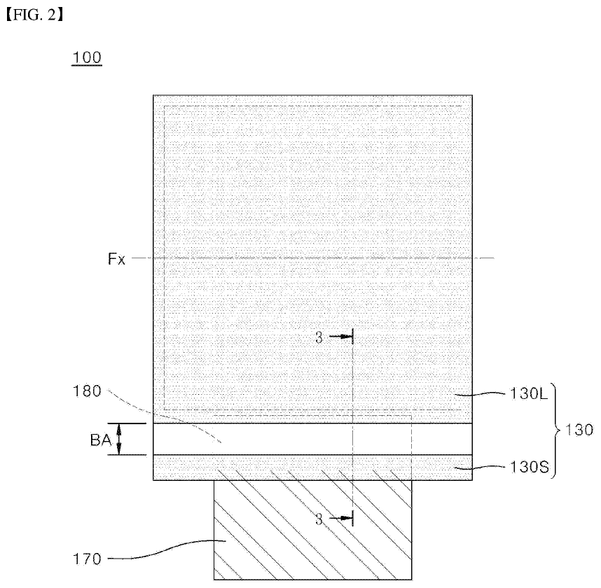

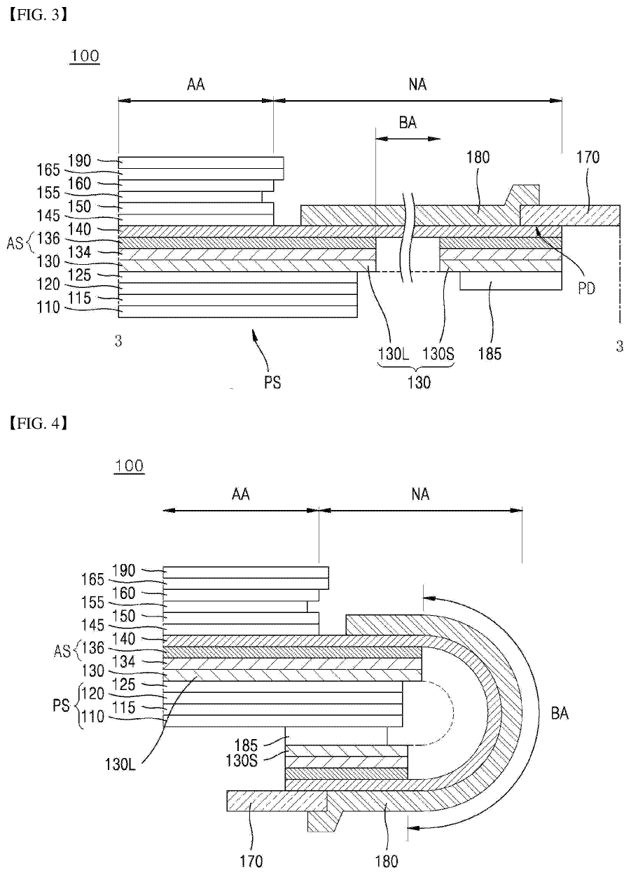

FIG. 1 is a plan view showing a state where a display apparatus according to an embodiment of the present disclosure is not bent. FIG. 2 is a rear view showing a state where a display apparatus according to an embodiment of the present disclosure is not bent. FIG. 3 is a sectional view cut away along 3-3 of FIG. 1. FIG. 4 is a sectional view showing that a display apparatus of FIG. 3 is bent.

Referring to FIGS. 1 and 2, a display panel 140 of a display apparatus 100 according to an embodiment of the present disclosure may include a display area (or active area) AA on which an image is displayed; and a non-display area NA disposed around the display area AA. The non-display area may include a bending area BA in which the display panel 140 is bendable; and a pad portion PD to which an external drive module is coupled.

The display apparatus 100 may be a foldable display device that may be folded or unfolded around a folding axis Fx within the display area AA. A folding method in which the display panel 140 is folded to make two display areas AA, disposed on both sides of the folding axis, face each other is called an In-Folding method. A folding method in which the display panel 140 is folded to make the two display areas AA, disposed on both sides of the folding axis Fx, face in opposite directions is called an Out-Folding method. When a plurality of folding axes are provided, the display area AA of the display apparatus 100 may be folded or unfolded into several areas. The display panel 140 may be a flexible display panel.

A plurality of sub-pixels may be disposed in the display area AA of the display panel 140 to display an image. Each of the sub-pixels may be a separate unit for emitting light, for example, red, blue, or white light. The embodiment is not limited thereto. A light emitting element and a pixel circuit unit for driving the light emitting element may be disposed in each of the sub-pixels disposed in the display area AA. The pixel circuit unit may include at least one thin film transistor, at least one capacitor, etc. The light emitting element may be an organic light emitting diode or an inorganic light emitting diode, for example.

The non-display area NA of the display panel may not display an image but may be the area in which a drive circuit for driving the plurality of sub pixels disposed in the display area AA and various wires are disposed. For example, a gate drive circuit and signal wires may be disposed in the non-display area NA. A data drive circuit may be further disposed in the non-display area NA. The gate drive circuit may be directly disposed on the display panel 140 in a GIP (Gate driver-In-Panel) method.

As shown in FIGS. 1 and 2, the non-display area NA may be the area surrounding an edge of the display area AA. In FIGS. 1 and 2, the non-display area NA surrounds the rectangular display area AA but the embodiment is not limited thereto. The display area AA and the non-display area NA may have appropriate shapes that are suitable for the design of an electronic device on which the display apparatus 100 is mounted. Exemplary shapes of the display area AA may include pentagonal, hexagonal, circular, elliptical shapes, etc., but the embodiment is not limited thereto.

A pad portion PD may be disposed on one side of the non-display area NA. An external drive module 170 may be coupled to the pad portion PD. The external drive module may include at least one of a flexible printed circuit board (FPCB) on which a timing controller and a power management IC are mounted or a chip film (COF) on which a data driver is mounted.

The bending area BA may be a part of the non-display area NA and it may be disposed between the display area AA and the pad portion PD. The bending area BA may be a predetermined area of the non-display area NA that is bendable to dispose the pad portion PD and the external drive module 170 coupled to the pad portion PD under the display panel 140.

The plurality of signal wires connected with the display area AA and the gate driver may be connected with the pad portion PD after passing the bending area BA of the non-display area NA. The plurality of signal wires passing through the bending area BA may include a plurality of data link lines, a high potential gate voltage wire, a low potential gate voltage wire, a clock wire, a start wire, a drive voltage wire, a ground voltage wire, an initialization voltage wire, etc.

When the pad portion PD and the external drive module 170 is disposed under the display panel as the non-display area NA of the display panel 140 is bent, the size of the non-display area NA, which is visible when viewed from above the display panel 140, may be reduced to realize narrow bezel.

A back plate 130 may be attached to a lower surface of the display panel 140. The back plate 130 may be attached to an area other than the bending area BA of the display panel 140 so that the bending area BA can be easily bent and have a small radius of curvature. A first back plate 130L and a second back plate 130S may be spaced apart from each other by the width of the bending area BA. The first back plate 130L may support the display area AA and some area of the non-display area NA adjacent to the display area AA. The second back plate 130S may support the non-display area NA in which the pad portion PD is disposed.

Referring to FIGS. 3 and 4, a polarization plate 150 may be attached to an upper surface of the display panel 140 in the display area AA of the display panel 140 by an adhesive layer 145. The polarization plate 150 may be disposed on the display panel 140 and configured to prevent reflection of light incident from the outside to improve visibility of the display panel 140. The polarization plate 150 may include a polarizer and a phase delay layer.

A cover window 160 may be attached on the polarization plate 150 by an adhesive layer 155.

The cover window 160 may be made of tempered glass or plastic film having impact resistance and light transmission in order to protect the display panel 140 from external impact, moisture and heat. To satisfy strength characteristics and folding characteristics, the cover window 160 may be formed with a thickness of 30 μm to 200 μm.

In case the cover window 160 is made of a plastic film, the cover window 160 may include polyimide (PI), polyethylene terephthalate (PET), polypropylene glycol (PPG) and Polycarbonate (PC) film.

In case the cover window 160 is made of tempered glass, the cover window 160 may be broken by external shock or stress. At this time, a protection film 190 may be attached on an upper surface of the cover window 160 by an adhesive layer 165 to prevent fragments of the cover window 160 from scattering. The protection film may include polyethylene terephthalate (PET), colorless polyimide (CPI) or a laminate of polyethylene terephthalate (PET) and colorless polyimide (CPI), for example. A hard coating layer, an anti-fingerprint layer or the like may be coated on an upper surface of the protection film 190.

The adhesive layers 145, 155 and 165 may be formed of a pressure-sensitive adhesive including an optically clear adhesive or the like. The adhesive layers 145, 155 and 165 may have a storage modulus in a range of 0.01 MPa to 0.1 MPa with respect to 25° C.

In the non-display area NA of the display panel 140, the external drive module 170 may be coupled to the pad portion PD disposed on the upper surface of the display panel 140 and a micro coating layer 180 may be disposed to cover at least the bending area BA.

The micro coating layer 180 may be disposed in an area between the display area AA of the display panel 140 and the external drive module 170 to cover the plurality of signal wires disposed in the non-display area NA of the display panel 140.

The micro coating layer 180 may prevent moisture from penetrating to the signal wires while protecting the signal wires from external shock. To suppress the penetration of moisture, one or more getter materials may be mixed into the micro coating layer 180. In addition, the micro coating layer 180 may supplement the rigidity of the display panel 140 in the bending area BA where the back plate is removed.

The micro coating layer 180 may be coated with a predetermined thickness to adjust the position of a neutral plane of the bending area BA. By disposing the micro coating layer 180 on the bending area BA, the neutral plane may be formed at the same position as the signal wires or at a higher position than the signal wires. By adjusting the position of the neutral plane of the bending area BA, the signal wires are not stressed or subjected to compressive stress during the bending and generation of cracks in the signal wires may be suppressed.

To prevent moisture from penetrating between the external drive module 170 and the pad portion PD, one end of the micro coating layer 180 may partially cover the external drive module 170. Since the micro coating layer 180 is disposed in the non-display area NA including the bending area BA, it is preferred that the micro coating layer 180 has a flexible characteristic. For example, the micro coating layer 180 may be made of acryl-based material such as acrylate polymer but the embodiment is not limited thereto.

The first back plate 130L and the second back plate 130S may be attached to a lower surface of the display panel 140 by an adhesion assembly AS.

The adhesion assembly AS may have a structure in which a first adhesive layer 134, a second adhesive layer 136 are multilayered with different storage elastic moduli. The second adhesive layer 136 may be an upper adhesive layer contacting the lower surface of the display panel 140. The first adhesive layer 134 may be a lower adhesive layer contacting the first back plate 130L and the second back plate 130S.

The first adhesive layer 134 may be a transparent adhesive, for example, a pressure-sensitive adhesive including a transparent optical adhesive. For example, the first adhesive layer 134 may have a storage modulus in a range of 0.01 MPa to 0.1 MPa based on 25° C.

The second adhesive layer 136 may have a higher storage modulus than the first adhesive layer 134. For example, the second adhesive layer 136 may have a storage modulus in a range of 0.1 MPa to 1 MPa based on 25° C.

The second adhesive layer 136 may be made of a variable adhesive of which adhesive force changes before and after heating.

The second adhesive layer 136 has a low adhesive force before heating so that it may be easily detached off after being attached. For example, after heating the second adhesive layer 136 at 50° C. for about 20 minutes, the adhesive force may increase so that the first and second back plates 130L and 130S may be stably attached to the lower surface of the display panel 140.

The second adhesive layer 136 may be made of a pressure-sensitive adhesive including hydrophobic silicone-acrylic copolymers.

Since the hydrophobic silicone-acrylic copolymers are distributed on the surface of the second adhesive layer 136 before heating, the adhesive force of the second adhesive layer 136 may low. When the heating is performed, the hydrophobic silicone-acrylic copolymers may start to spread into the second adhesive layer 136 so that the surface of the second adhesive layer 136 may become hydrophilic and the adhesive force of the second adhesive layer 136 may increase.

The second adhesive layer 136 may include one or more pigments, dyes or a mixture thereof as a colorant. The second adhesive layer 136 may include a black pigment or dye so as to appear black or gray, for example. The second adhesive layer 136 may include a red pigment or dye, a green pigment or dye and a blue pigment or dye so as to appear black or gray.

Since the second adhesive layer 136 disposed on the lower surface of the display panel 140 has a black or gray color, the external incident light having passed through the display panel 140 may be absorbed by the second adhesive layer 136 and the visibility of the display panel 140 may be improved.

The thickness of the second adhesive layer 136 may be smaller than that of the first adhesive layer 134. The thickness of the second adhesive layer 136 may be a half or less of the thickness of the first adhesive layer 134. The thickness of the second adhesive layer 136 may be 3 μm to 7 μm and the thickness of the first adhesive layer 134 may be 10 μm to 20 μm.

The adhesion assembly AS may have a storage modulus similar to that of the first adhesive layer 134 by increasing the ratio of the first adhesive layer 134 having a low storage modulus in the adhesion assembly AS. Accordingly, the adhesion assembly AS may relieve stress in the folding area of the display apparatus 100.

An end of the first back plate 130L may be closer to the bending area BA than an end of the cover window 160, an end of the protection film 190 and an end of the polarization plate 150.

A support structure PS may be disposed under the first back plate 130L and support the display panel 140. The support structure PS may facilitate the folding and unfolding of the display panel 140. The support structure PS may be configured to dissipate heat generated from the display panel 140 outside. The support structure PS may include a folding area having a folding axis (Fx, see FIG. 1) and non-folding areas provided on both sides of the folding area.

The support structure PS may include at least one support plate and at least one adhesive layer. The support structure PS may include a first support plate 110 and a second support plate 120. The support structure PS may include an adhesive layer 115 disposed between the first support plate 110 and the second support plate 120, and an adhesive layer 125 disposed on the second support plate 120. The support structure PS may be attached on a lower surface of the first back plate 130L by the adhesive layer 125. The first support plate 110 may be a lower support plate and the second support plate 120 may be an upper support plate. The support structure PS may be a plate assembly. The adhesive layers 115 and 125 may be transparent and made of a pressure-sensitive adhesive PSA including an optically clear adhesive OCA. The adhesive layers 115 and 125 may have a storage modulus in a range of 0.01 MPa to 0.1 MPa based on 25° C., for example.

The first support plate 110 may be made of metal with excellent thermal conductivity. For example, the first support plate 110 may be made of stainless steel. The first support plate 110 may have a plurality of opening patterns formed in the folding area. The plurality of opening patterns may extend in a direction parallel with the folding axis Fx (hereinafter, a folding axis direction) and may be provided in a discontinuous form. The length of each opening pattern may be shorter than the folding-axis-direction width of the first support plate 110. Intervals of the opening patterns adjacent to each other in a direction perpendicular to the folding axis Fx may become wider as getting farther from the folding axis Fx. The opening patterns adjacent to each other in the direction perpendicular to the folding axis Fx may have a first interval at a central portion adjacent to the folding axis Fx, and may have a second interval larger than the first interval at edge portions on both sides of the central portion.

An adhesive member 185 may be disposed on a lower surface of the second back plate 130S. The adhesive member 185 may be a pressure sensitive adhesive or double-sided tape. As shown in FIG. 4, in a state where the display panel 140 is bent, the second back plate 130S may be fixedly attached to a lower surface of the support structure PS, that is, a lower surface of the first support plate 110.

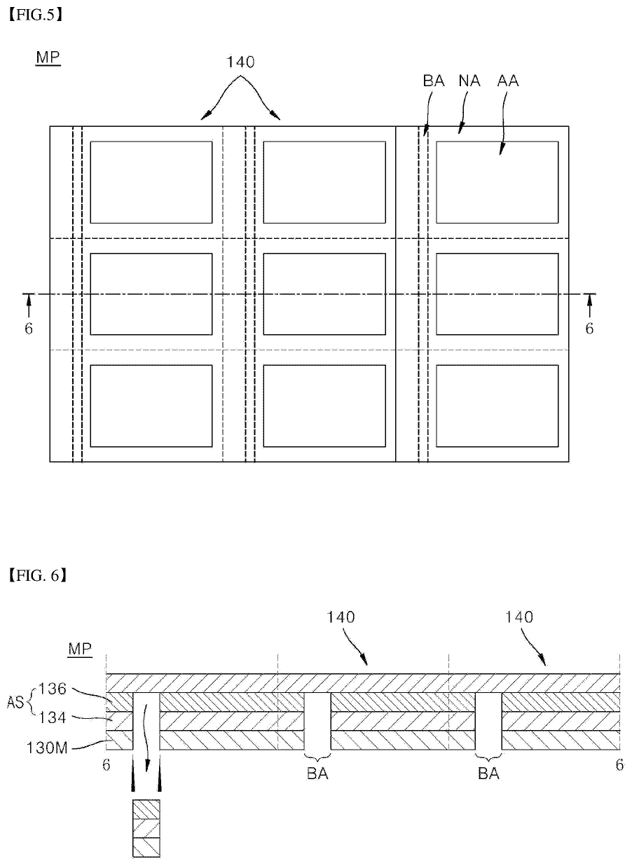

FIGS. 5 and 6 are views showing a process of attaching a back plate to a display panel using the adhesion assembly according to an embodiment of the present disclosure.

Referring to FIGS. 5 and 6, a plurality of display panels 140 including a display area AA, a non-display area NA and a bending area BA may be formed on a mother substrate MP.

A mother back plate 130M may be attached to a lower surface of the mother substrate MP, on which the plurality of display panels 140 are formed, by the adhesion assembly AS. The adhesion assembly AS may include the first adhesive layer 134 and the second adhesive layer 136.

Since the second adhesive layer 136 is made of a variable adhesive in which an adhesive force is variable, the second adhesive layer 136 may have a weak adhesive force before being heated and may be locally cut and peeled off by laser irradiation. After the laser is irradiated along both edges of the bending area BA, a predetermined area of the second adhesive layer 136, a predetermined area of the first adhesive layer 134 and a predetermined area of the mother back plate 130M, disposed in the bending area BA, may be easily peeled off.

Next, heat may be applied to the second adhesive layer 136 and the adhesive force of the second adhesive layer 136 may be increased. Then, the mother substrate MP may be cut into individual display panels 140 after that. Accordingly, the first and second back plates stably attached to each of the display panels 140 may be formed.

After the mother back plate 130M is attached to the mother substrate MP, predetermined areas of the mother back plates 130M disposed in the bending areas BA of the plurality of display panels 140 disposed in the same column may be removed at once. Accordingly, the manufacturing time and costs may be reduced.

Although the present disclosure is mainly described herein with reference to a foldable display device, the present disclosure is not limited to the foldable display device, but can be applied to any suitable display device.

The display apparatus according to the embodiments of the present disclosure may be described as follows.

The display apparatus according to the embodiments of the present disclosure may include the display panel including the display area in which the plurality of sub-pixels are aligned; the first back plate and the second back plate disposed below the display panel and spaced apart from each other; and the adhesion assembly attaching the first back plate and the second back plate to the lower surface of the display panel. The adhesion assembly may have the multilayer structure in which the plurality of adhesive layers with different storage moduli are disposed.

According to several embodiments of the present disclosure, the adhesion assembly may include a first adhesive layer contacting the first back plate and the second back plate; and a second adhesive layer contacting the display panel, and the second adhesive layer may have a larger storage modulus than the first adhesive layer.

The second adhesive layer may have a storage modulus in a range of 0.1 MPa to 1 MPa based on 25° C., and the first adhesive layer may have a storage modulus in a range of 0.01 MPa to 0.1 MPa based on 25° C.

According to several embodiments of the present disclosure, the second adhesive layer may include a black pigment or dye.

According to several embodiments of the present disclosure, the second adhesive layer may include a red pigment or dye, a green pigment or dye and a blue pigment or dye so as to appear black or gray.

According to several embodiments of the present disclosure, the thickness of the second adhesive layer may be smaller than that of the first adhesive layer.

According to several embodiments of the present disclosure, the thickness of the second adhesive layer may be 3 μm to 7 μm, and the thickness of the first adhesive layer is 10 μm to 20 μm.

According to several embodiments of the present disclosure, the second adhesive layer may be a pressure-sensitive adhesive comprising hydrophobic silicone-acrylic copolymers.

The display apparatus according to the embodiments of the present disclosure may include a flexible display panel; a back plate disposed under the flexible display panel; and an adhesion assembly attaching the back plate to a lower surface of the flexible display panel. The adhesion assembly may include a first adhesive layer contacting the back plate; and a second adhesive layer contacting the flexible display panel, and the second adhesive layer may have a larger storage modulus than the first adhesive layer.

According to several embodiments of the present disclosure, the second adhesive layer may have a storage modulus in a range of 0.1 MPa to 1 MPa based on 25° C., and the first adhesive layer may have a storage modulus in a range of 0.01 MPa to 0.1 MPa based on 25° C.

According to several embodiments of the present disclosure, the second adhesive layer may include a black pigment or dye.

According to several embodiments of the present disclosure, the second adhesive layer may include a red pigment or dye, a green pigment or dye and a blue pigment or dye so as to appear black or gray.

According to several embodiments of the present disclosure, the thickness of the second adhesive layer may be smaller than that of the first adhesive layer.

According to several embodiments of the present disclosure, the second adhesive layer may be a pressure-sensitive adhesive comprising hydrophobic silicone-acrylic copolymers.

According to several embodiments of the present disclosure, the flexible display panel may include a display area and a non-display area surrounding the display area and having a bending area. The back plate may include a first back plate disposed in the display area and a non-display area adjacent to the display area; and a second back plate disposed in an area of the non-display area in which a pad is provided.

According to several embodiments of the present disclosure, the display apparatus such as a foldable display apparatus may further include a cover window and a protection film that are disposed on the flexible display panel.

According to several embodiments of the present disclosure, an end of the first back plate may be closer to the bending area than an end of the cover window and an end of the protection film.

Although the present invention has been described with reference to the exemplified drawings, it is to be understood that the present invention is not limited to the embodiments and drawings disclosed in this specification, and those skilled in the art will appreciate that various modifications are possible without departing from the scope and spirit of the present invention. Further, although the operating effects according to the configuration of the present invention are not explicitly described while describing an embodiment of the present invention, it should be appreciated that predictable effects are also to be recognized by the configuration.

What is claimed is:

1. A display apparatus comprising:
a display panel comprising a display area having a plurality of sub-pixels and a non-display area surrounding the display area and having a bending area;
a first back plate and a second back plate disposed under the display panel and spaced apart from each other; and
an adhesion assembly attaching the first back plate and the second back plate to a lower surface of the display panel,
wherein the adhesion assembly has a multilayer structure in which a plurality of adhesive layers with different storage moduli are disposed.

2. The display apparatus of claim 1, wherein the adhesion assembly includes a variable adhesive layer contacting the lower surface of the display panel.

3. The display apparatus of claim 1, wherein the adhesion assembly comprises:
a first adhesive layer contacting the first back plate and the second back plate; and
a second adhesive layer contacting the display panel, and
the second adhesive layer has a larger storage modulus than the first adhesive layer.

4. The display apparatus of claim 3, wherein the second adhesive layer has a storage modulus in a range of 0.1 MPa to 1 MPa based on 25° C., and the first adhesive layer has a storage modulus in a range of 0.01 MPa to 0.1 MPa based on 25° C.

5. The display apparatus of claim 3, wherein the second adhesive layer comprises a black pigment or dye.

6. The display apparatus of claim 3, wherein the second adhesive layer comprises a red pigment or dye, a green pigment or dye and a blue pigment or dye so as to appear black or gray.

7. The display apparatus of claim 3, wherein a thickness of the second adhesive layer is smaller than a thickness of the first adhesive layer.

8. The display apparatus of claim 3, wherein the thickness of the second adhesive layer is 3 μm to 7 μm, and the thickness of the first adhesive layer is 10 μm to 20 μm.

9. The display apparatus of claim 3, wherein the second adhesive layer is a pressure-sensitive adhesive comprising hydrophobic silicone-acrylic copolymers.

10. A foldable display apparatus comprising:
a flexible display panel;
a back plate disposed under the flexible display panel; and
an adhesion assembly attaching the back plate to a lower surface of the flexible display panel,
wherein the adhesion assembly comprises:
a first adhesive layer contacting the back plate; and
a second adhesive layer contacting the flexible display panel, and
the second adhesive layer has a larger storage modulus than the first adhesive layer.

11. The foldable display apparatus of claim 10, wherein the second adhesive layer is made of a variable adhesive.

12. The foldable display apparatus of claim 10, wherein the second adhesive layer has a storage modulus in a range of 0.1 MPa to 1 MPa based on 25° C., and the first adhesive layer has a storage modulus in a range of 0.01 MPa to 0.1 MPa based on 25° C.

13. The foldable display apparatus of claim 10, wherein the second adhesive layer comprises a black pigment or dye.

14. The foldable display apparatus of claim 10, wherein the second adhesive layer comprises a red pigment or dye, a green pigment or dye and a blue pigment or dye so as to appear black or gray.

15. The foldable display apparatus of claim 10, wherein a thickness of the second adhesive layer is smaller than a thickness of the first adhesive layer.

16. The foldable display apparatus of claim 10, wherein the second adhesive layer is a pressure-sensitive adhesive comprising hydrophobic silicone-acrylic copolymers.

17. The foldable display apparatus of claim 10, wherein the flexible display panel comprising a display area and a non-display area surrounding the display area and having a bending area,
the back plate comprises a first back plate disposed in the display area and a non-display area adjacent to the display area; and a second back plate disposed in an area of the non-display area in which a pad is provided.

18. The foldable display apparatus of claim 17, further comprising:
a cover window and a protection film which are disposed on the flexible display panel.

19. The foldable display apparatus of claim 18, wherein an end of the first back plate is closer to the bending area than an end of the cover window and an end of the protection film.
